(19) United States
(12) Patent Application Publication
(10) Pub. No.: US 2024/0286389 A1
(43) Pub. Date: Aug. 29, 2024

(54) PROTECTIVE COVER MEMBER, SHEET FOR MEMBER SUPPLY, AND MICROELECTROMECHANICAL SYSTEM

(71) Applicant: NITTO DENKO CORPORATION, Osaka (JP)

(72) Inventors: Eisaku TANAKA, Osaka (JP); Takeo INOUE, Osaka (JP); Kyoko ISHII, Osaka (JP)

(73) Assignee: NITTO DENKO CORPORATION, Osaka (JP)

(21) Appl. No.: 18/573,110

(22) PCT Filed: Jul. 1, 2022
(86) PCT No.: PCT/JP2022/026516

§ 371 Date: Dec. 21, 2023

(30) Foreign Application Priority Data
Jul. 2, 2021 (JP) 2021-111046

(51) Int. Cl. B32B 27/06; B32B 5/18; B32B 27/08; B32B 27/32; B32B 27/36; C09J 11/04; C09J 133/08; C09J 161/06; C09J 163/00

(52) U.S. Cl. CPC B32B 27/065; B32B 5/18; B32B 27/08; B32B 27/322; B32B 27/36; C09J 11/04; C09J 133/08; C09J 161/06; C09J 163/00; B32B 2250/02; B32B 2250/24; B32B 2255/10; B32B 2255/26; B32B 2266/025; B32B 2307/724; B32B 2307/737; B32B 2457/00

(57) ABSTRACT

A provided protective cover member is a member configured to be placed on a face of an object, the face having an opening. The protective cover member includes a laminate, and the laminate includes: a protective membrane having a shape configured to cover the opening when the protective cover member is placed on the face; and an adhesive layer. When a portion, of the protective membrane, coinciding with the adhesive layer when viewed in a direction perpendicular to a principal surface of the protective membrane is defined as a fixed portion of the protective membrane, an exposed surface of the protective membrane on a side opposite to a side, of the protective membrane, facing the adhesive layer has a region A overlapping the fixed portion when viewed in the perpendicular direction and having a contact angle of 55 degrees or more for methanol.

### TECHNICAL FIELD

The present invention relates to a protective cover member configured to be placed on a face of an object, the face having an opening, a member supplying tape for supplying the protective cover member, and a micro electro mechanical system including the protective cover member.

### BACKGROUND ART

Protective cover members configured to be placed on a face of an object to prevent entrance of foreign matter into an opening of the face are known. Patent Literature 1 discloses a member including: a porous membrane including polytetrafluoroethylene (hereinafter referred to as “PTFE”) as a main component and allowing sound to pass therethrough but preventing foreign matter such as a water drop from passing therethrough; and a heat-resistant double-sided adhesive sheet which is an adhesive layer placed on a limited region of at least one principal surface of the porous membrane in order to fix the porous membrane to another component. In Patent Literature 1, by focusing on a substrate of the heat-resistant double-sided adhesive sheet configured to fix the member to a surface of a circuit board which is an object, an attempt is made to ensure heat resistance of the member at high temperatures in reflow soldering.

### CITATION LIST

### Patent Literature

Patent Literature 1: JP 2007-081881 A

### SUMMARY OF INVENTION

### Technical Problem

Recently, there is a demand for placement of a protective cover member over an opening of a tiny product such as a micro electro mechanical system (hereinafter referred to as “MEMS”). There is also a demand for placement of a protective cover member on a face inside of a product as well as on an outer surface. To satisfy the demands, the area of such a protective membrane has been more decreased. Under such circumstances, decreasing the area of an adhesive layer that prevents passage of gas and sound, such as decreasing the width of the adhesive layer placed on a peripheral portion of the protective membrane, is unavoidable in order to allow passage of gas and/or sound through the protective membrane as much as possible.

The present invention aims to provide a protective cover member including a protective membrane and an adhesive layer and suitable for reducing the area of the adhesive layer.

### Solution to Problem

The present invention provides a protective cover member configured to be placed on a face of an object, the face having an opening, the protective cover member including a laminate, wherein
the laminate includes: a protective membrane having a shape configured to cover the opening when the protective cover member is placed on the face; and an adhesive layer, and
when a portion, of the protective membrane, coinciding with the adhesive layer when viewed in a direction perpendicular to a principal surface of the protective membrane is defined as a fixed portion of the protective membrane, an exposed surface of the protective membrane on a side opposite to a side, of the protective membrane, facing the adhesive layer has a region A overlapping the fixed portion when viewed in the perpendicular direction and having a contact angle of 55 degrees or more for methanol.

In another aspect, the present invention provides a member supplying sheet including:
a substrate sheet; and
at least one protective cover member placed on the substrate sheet, wherein
the protective cover member is the above protective cover member of the present invention.

In another aspect, the present invention provides a micro electro mechanical system including the above protective cover member of the present invention.

### Advantageous Effects of Invention

According to the present invention, a protective cover member including a protective membrane and an adhesive layer and suitable for reducing the area of the adhesive layer is achieved.

### BRIEF DESCRIPTION OF THE DRAWINGS

FIG. 1A is a cross-sectional view schematically showing an example of a protective cover member of the present invention.

FIG. 1B is a plan view of the protective cover member 1 of FIG. 1A viewed from a protective membrane 2 side.

FIG. 1C is a plan view of the protective cover member 1 of FIG. 1A viewed from an adhesive layer 3 side.

FIG. 2A is a schematic diagram for describing protrusion of a fluid when an exposed surface of a protective membrane does not have a region A.

FIG. 2B is a schematic diagram showing an example of a state that the fluid can take when the exposed surface of the protective membrane has the region A.

FIG. 3 is a cross-sectional view schematically showing an example of the protective cover member of the present invention.

FIG. 4 is a cross-sectional view schematically showing an example of an embodiment of placement of the protective cover member of the present invention on an object.

FIG. 5 is a cross-sectional view schematically showing an example of an embodiment of placement of the protective cover member of the present invention on an object.

FIG. 6 is a cross-sectional view schematically showing an example of the protective cover member of the present invention.

FIG. 7 is a cross-sectional view schematically showing an example of the protective cover member of the present invention.

FIG. 8 is a plan view schematically showing an example of a member supplying sheet of the present invention.

### DESCRIPTION OF EMBODIMENTS

A protective cover member according to a first aspect of the present invention is a protective cover member configured to be placed on a face of an object, the face having an opening, the protective cover member including a laminate, wherein
the laminate includes: a protective membrane having a shape configured to cover the opening when the protective cover member is placed on the face; and an adhesive layer, and
when a portion, of the protective membrane, coinciding with the adhesive layer when viewed in a direction perpendicular to a principal surface of the protective membrane is defined as a fixed portion of the protective membrane, an exposed surface of the protective membrane on a side opposite to a side, of the protective membrane, facing the adhesive layer has a region A overlapping the fixed portion when viewed in the perpendicular direction and having a contact angle of 55 degrees or more for methanol.

In a second aspect of the present invention, for example, in the protective cover member according to the first aspect, an entire exposed surface of the fixed portion on the opposite side has a contact angle of 55 degrees or more for methanol.

In a third aspect of the present invention, for example, in the protective cover member according to the first or second aspect, the fixed portion is positioned in a peripheral portion of the protective membrane when viewed in the perpendicular direction.

In a fourth aspect of the present invention, for example, in the protective cover member according to any one of the first to third aspects, the adhesive layer is in contact with the protective membrane.

In a fifth aspect of the present invention, for example, in the protective cover member according to any one of the first to fourth aspects, the adhesive layer is positioned on a side of placement of the protective cover member on the face of the object with respect to the protective membrane.

In a sixth aspect of the present invention, for example, in the protective cover member according to any one of the first to fifth aspects, the adhesive layer includes a layer formed of a thermosetting adhesive agent composition.

In a seventh aspect of the present invention, for example, in the protective cover member according to the sixth aspect, the thermosetting adhesive agent composition has a storage modulus of 1.0×10³ Pa or more at 130 to 170° C.

In an eighth aspect of the present invention, for example, in the protective cover member according to the sixth or seventh aspect, the thermosetting adhesive agent composition has a storage modulus of 1.0×10⁸ Pa or less at 130 to 170° C. after thermal curing.

In a ninth aspect of the present invention, for example, in the protective cover member according to any one of the first to eighth aspects, when viewed in the direction perpendicular to the principal surface of the protective membrane, the adhesive layer is placed on a peripheral portion of the protective membrane, and a ratio L₂/L₁ of a length L₂ of a portion of a shortest line segment of line segments extending from a center of the protective membrane to a perimeter of the protective membrane to a length L₁ of the shortest line segment is 0.5 or less, the portion lying over the adhesive layer.

In a tenth aspect of the present invention, for example, in the protective cover member according to any one of the first to ninth aspects, the protective membrane has gas permeability in a thickness direction of the protective membrane.

In an eleventh aspect of the present invention, for example, in the protective cover member according to any one of the first to tenth aspects, the protective membrane includes a porous membrane or a microporous membrane, and the porous membrane and the microporous membrane each have an average pore diameter of 0.01 μm or more and less than 3 μm.

In a twelfth aspect of the present invention, for example, in the protective cover member according to any one of the first to eleventh aspects, the protective membrane includes a polytetrafluoroethylene membrane.

In a thirteenth aspect of the present invention, for example, in the protective cover member according to any one of the first to twelfth aspects, the protective membrane has an area of 175 mm² or less.

In a fourteenth aspect of the present invention, for example, in the protective cover member according to any one of the first to thirteenth aspects, the laminate further includes a substrate film positioned on the adhesive layer side with respect to the protective membrane.

In a fifteenth aspect of the present invention, for example, the protective cover member according to any one of the first to fourteenth aspects is for a micro electro mechanical system (MEMS).

In a sixteenth aspect of the present invention, for example, the protective cover member according to the fifteenth aspect is placed and used inside the MEMS.

A member supplying sheet according to a seventeenth aspect of the present invention includes:
a substrate sheet; and
at least one protective cover member placed on the substrate sheet, wherein
the protective cover member is the protective cover member according to any one of the first to sixteenth aspects.

A micro electro mechanical system according to an eighteenth aspect includes the protective cover member according to any one of the first to sixteenth aspects.

Embodiments of the present invention will be described with reference to the drawings. The present invention is not limited to the following embodiments.

### [Protective Cover Member]

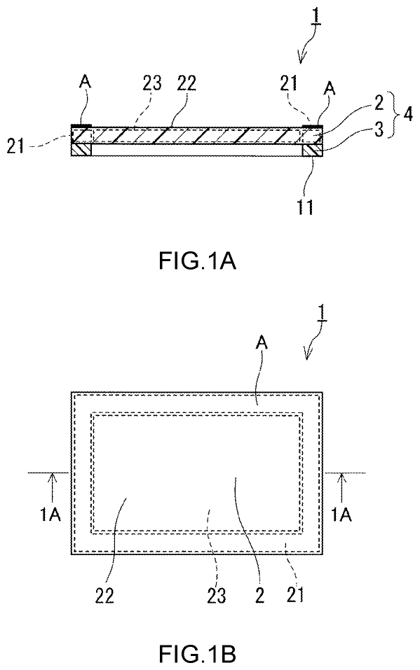

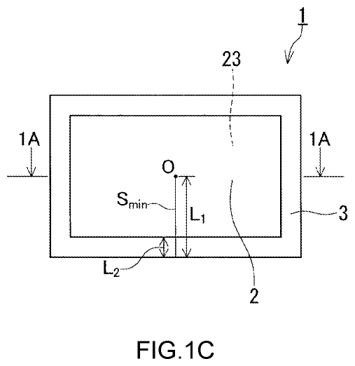

FIGS. 1A, 1B, and 1C show an example of a protective cover member of the present embodiment. FIG. 1B is a plan view of the protective cover member 1 of FIG. 1A viewed from a protective membrane 2 side. FIG. 1C is a plan view of the protective cover member 1 of FIG. 1A viewed from an adhesive layer 3 side. FIG. 1A shows a cross-section 1A-1A of FIGS. 1B and 1C. In FIGS. 1B and 1C, the protective cover member 1 is viewed in a direction perpendicular to a principal surface of the protective membrane 2. The protective cover member 1 is a member configured to be placed on a face (placement face) of an object, the face having an opening. By placing the protective cover member 1 on the placement face, for example, entrance of foreign matter into and/or from the opening, i.e., entrance of foreign matter through the opening, can be prevented. The protective cover member 1 includes a laminate 4 including a protective membrane 2 and an adhesive layer 3. The protective membrane 2 has a shape configured to cover the opening when the protective cover member 1 is placed on the placement face. The adhesive layer 3 is joined to the protective membrane 2. The protective cover member 1 can be fixed to the placement face of the object by the adhesive layer 3.

A portion of the protective membrane 2 that coincides with the adhesive layer 3 when viewed in the direction perpendicular to the principal surface of the protective membrane 2 can be defined as a fixed portion 21 of the protective membrane 2. An exposed surface 22 of the protective membrane 2 has a region A overlapping the fixed portion 21 when viewed in the direction perpendicular to the principal surface of the protective membrane 2 and having a contact angle θ_{M} of 55 degrees or more for methanol. The exposed surface 22 is on a side opposite to a side facing the adhesive layer 3.

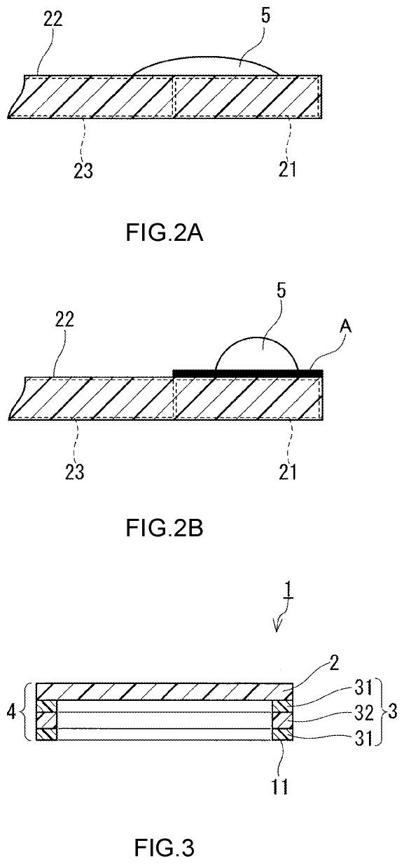

When the adhesive layer 3 has a reduced area, it becomes difficult to join the protective membrane 2 and the adhesive layer 3 and maintain the joining. In order to more reliably join the protective membrane 2 and the adhesive layer 3, it is conceivable to use a heating/pressing treatment such as hot-pressing. However, according to the studies by the present inventors, it was found that, especially when the protective membrane 2 and the adhesive layer 3 are joined using a heating/pressing treatment, the gas permeability and the sound transmission of the protective cover member 1 tend to be impaired when another member is combined on a side opposite to the adhesive layer 3 side of the protective membrane 2, not on the adhesive layer 3 side. According to further studies, the above tendency is typically due to the fact that a fluid 5, such as a treatment liquid for a surface treatment performed on the protective membrane 2 before placing another member or an adhesive agent for joining another member to the protective cover member 1, spreads from the fixed portion 21 of the protective membrane 2 to a gas passage/sound passage region 23 and blocks the region 23 (see FIG. 2A). In the protective cover member 1 of the present embodiment, since the exposed surface 22 has the region A, the protrusion of the fluid 5 from the fixed portion 21 to the gas passage/sound passage region 23 can be suppressed (see FIG. 2B). The surface tension (20° C.) of an organic solvent normally contained in an adhesive agent or the like is usually in the range of 20 to 40 mN/m. In consideration of this, the contact angle θ_{M} for methanol having a surface tension (22.5 mN/m; 20° C.) close to the lower limit of the above range is specified.

The contact angle θ_{M} of the region A may be 58 degrees or more, 60 degrees or more, 63 degrees or more, 65 degrees or more, 68 degrees or more, 70 degrees or more, 73 degrees or more, or even 75 degrees or more. The upper limit of the contact angle θ_{M} of the region A is, for example, 130 degrees or less, and may be 120 degrees or less, 110 degrees or less, 100 degrees or less, 90 degrees or less, 85 degrees or less, 80 degrees or less, 75 degrees or less, or even less than 73 degrees. The contact angle θ_{M} can be evaluated according to the sessile drop method specified in the Japanese Industrial Standards (hereinafter referred to as JIS) R3257 (however, a methanol drop having a volume of 2 μL is used instead of a water drop). The evaluation temperature is set to 25° C.

The contact angle θ_{M} of the region A varies depending on, for example, the material and the characteristics (thickness, average pore diameter, porosity, state of the exposed surface 22, surface free energy, surface roughness, etc.) of the protective membrane 2, the presence or absence of various treatments on the protective membrane 2, the characteristics (thickness, storage modulus, surface free energy, etc.) of the adhesive layer 3, the constitution and the characteristics (storage modulus, surface free energy, etc.) of an adhesive agent composition used for forming the adhesive layer 3, the conditions for joining the protective membrane 2 and the adhesive layer 3, etc.

The shape of the region A is not limited as long as the region A overlaps the fixed portion 21 when viewed in the direction perpendicular to the principal surface of the protective membrane 2. If the contact angle θ_{M} of the overlapping portion with the fixed portion 21 in the region A is a certain angle θ₁ (e.g., 55 degrees) or more, the contact angle θ_{M} of the region A is determined to be 01 or more.

In the protective cover member 1 of FIGS. 1A to 1C, the entire exposed surface 22 of the fixed portion 21 on the opposite side, in other words, the entire portion of the exposed surface 22 that coincides with the fixed portion 21 when viewed in the direction perpendicular to the principal surface of the protective membrane 2, has a contact angle θ_{M} of 55 degrees or more.

The fixed portion 21 of FIGS. 1A to 1C is positioned in a peripheral portion of the protective membrane 2 when viewed in the direction perpendicular to the principal surface of the protective membrane 2. In addition, the shape of the fixed portion 21 of FIGS. 1A to 1C has a frame shape when viewed in the above perpendicular direction. However, the shape of the fixed portion 21 and the position of the fixed portion 21 in the protective membrane 2 are not limited to the above example. The region 23 surrounded by the fixed portion 21 in the protective membrane 2 when viewed in the above perpendicular direction can be a gas passage/sound passage region through which gas and/or sound can mainly pass in the protective cover member 1.

The area of the region 23 is, for example, 20 mm² or less, and may be 15 mm² or less, 12.5 mm² or less, 10 mm² or less, 7.5 mm² or less, 5 mm² or less, 2.5 mm² or less, 2 mm² or less, or even 1.5 mm² or less. The protective cover member 1 in which the area of the region 23 is in the above range is suitable, for example, for being placed on a circuit board or MEMS that normally has a small-diameter opening. The lower limit of the area of the region 23 is, for example, 0.008 mm² or more. However, the area of the region 23 may be in a larger range depending on the type of an object on which the protective cover member 1 is placed.

The region A and the region 23 may overlap each other when viewed in the direction perpendicular to the principal surface of the protective membrane 2.

The adhesive layer 3 of FIGS. 1A to 1C is in contact with the protective membrane 2. More specifically, the adhesive layer 3 is joined to the protective membrane 2. However, another layer may be placed between the adhesive layer 3 and the protective membrane 2. A heating/pressing treatment such as hot-pressing may be used for joining the adhesive layer 3 and the protective membrane 2.

A component contained in the adhesive layer 3 (hereinafter referred to as component of the adhesive layer 3) may or may not permeate into the interior of the protective membrane 2. When the component of the adhesive layer 3 permeates into the interior of the protective membrane 2, the permeation does not have to reach the exposed surface 22 of the protective membrane 2. The fact that the permeation does not reach the exposed surface 22, including an embodiment of not permeating into the interior of the protective membrane 2, can contribute to the exposed surface 22 having the region A. According to the studies by the present inventors, the permeation of the component of the adhesive layer 3 is likely to occur upon joining the adhesive layer 3 and the protective membrane 2, especially when the adhesive layer 3 is a layer formed of a thermosetting adhesive agent composition or when the adhesive layer 3 and the protective membrane 2 are joined using a heating/pressing treatment.

The degree of permeation of the component of the adhesive layer 3 into the interior of the protective membrane 2 can be represented, for example, by a maximum permeation depth of the component into the protective membrane 2. The maximum permeation depth may be less than the thickness of the protective membrane 2, and may be 95% or less, 90% or less, 70% or less, 50% or less, 30% or less, or even 10% or less of the thickness of the protective membrane 2.

The adhesive layer 3 of FIGS. 1A to 1C is placed in a partial region of the protective membrane 2 when viewed in the direction perpendicular to the principal surface of the protective membrane 2. The adhesive layer 3 is in a shape that is the shape of the peripheral portion of the protective membrane 2 when viewed in the above perpendicular direction. More specifically, the adhesive layer 3 is in the shape of a frame shape when viewed in the above perpendicular direction. More favorable passage of gas and/or sound can be achieved in the region 23 of the protective membrane 2 where the adhesive layer 3 is not placed than in a region where the adhesive layer 3 is placed. However, the shape of the adhesive layer 3 is not limited to the above example. For example, when the protective membrane 2 is circular when viewed in the direction perpendicular to the principal surface, the adhesive layer 3 may be in a ring shape when viewed in the above perpendicular direction.

The thickness of the adhesive layer 3 is, for example, 3 to 200 μm, and may be 5 to 100 μm, 10 to 50 μm, or even 20 to 40 μm.

The total area of the adhesive layer 3 is, for example, 0.1 to 10 mm², and may be 0.5 to 5 mm², 0.8 to 4 mm², or even 1 to 3 mm². The width of the adhesive layer 3 having a frame shape (also corresponding to the width of the fixed portion 21) is, for example, 50 to 3000 μm, and may be 100 to 1000 μm, 150 to 800 μm, or even 200 to 500 μm.

The adhesive layer 3 of FIGS. 1A to 1C is placed on the peripheral portion of the protective membrane 2 when viewed in the direction perpendicular to the principal surface of the protective membrane 2. In this case, when viewed in the above perpendicular direction, a ratio L₂/L₁ may be 0.5 or less, 0.3 or less, 0.2 or less, or even 0.1 or less, where L₁ is the length of a shortest line segment Sₘᵢₙ of line segments extending from a center O of the protective membrane 2 to the perimeter of the protective membrane 2, and L₂ is the length of a portion of the line segment Sₘᵢₙ, the portion lying over the adhesive layer 3. The lower limit of the ratio L₂/L₁ is, for example, 0.05 or more. The center O of the protective membrane 2 can be determined as the center of gravity of the shape of the protective membrane 2, the shape being defined when viewed in the direction perpendicular to the principal surface of the protective membrane 2.

The adhesive layer 3 includes a layer formed of an adhesive agent composition (hereinafter referred to as layer B). The adhesive layer 3 may have a single-layer structure composed of the layer B or a laminate structure including the layer B. The laminate structure may have two or more layers B.

The adhesive layer 3 may include a substrate and the layer B placed on at least one surface of the substrate. FIG. 3 shows an example of such an embodiment. The adhesive layer 3 of FIG. 3 has a substrate 32 and two layers B31 provided on both surfaces of the substrate 32, respectively. One layer B31 is in contact with the protective membrane 2. The other layer B31 forms a joining surface 11 of the protective cover member 1 to the placement face of the object. The configurations of the respective layers B31 may be the same or different from each other.

The substrate 32 is, for example, a film, non-woven fabric, or foam made of a resin, metal, or composite material thereof. Examples of the resin include polyolefins such as polyethylene and polypropylene, polyesters such as polyethylene terephthalate (PET), silicone resins, polycarbonates, polyimides, polyamide-imides, polyphenylene sulfide, polyetheretherketone (PEEK), and fluorine resins. Examples of the fluorine resins include polytetrafluoroethylene (PTFE), tetrafluoroethylene-perfluoroalkyl vinyl ether copolymer (PFA), tetrafluoroethylene-hexafluoropropylene copolymer (FEP), and tetrafluoroethylene-ethylene copolymer (ETFE). Examples of the metal include stainless steel and aluminum. However, the resin and the metal are not limited to the above examples.

The substrate 32 may include a heat-resistant material. The protective cover member 1 that includes the substrate 32 including a heat-resistant material is suitable for use at high temperatures, depending on the materials of the other layers of the protective cover member 1. Examples of the heat-resistant material include a metal and a heat-resistant resin. The heat-resistant resin typically has a melting point of 150° C. or higher. The heat-resistant resin may have a melting point of 160° C. or higher, 200° C. or higher, 220° C. or higher, 240° C. or higher, 250° C. or higher, 260° C. or higher, or even 300° C. or higher. Examples of the heat-resistant resin include a silicone resin, a polyimide, a polyamide-imide, polyphenylene sulfide, PEEK, and a fluorine resin. The fluorine resin may be PTFE. PTFE is excellent particularly in heat resistance.

Examples of the adhesive agent composition that can form the layer B31 include a thermosetting adhesive agent composition, a pressure-sensitive adhesive agent composition, and an ultraviolet (UV)-curable adhesive agent composition. The layer B31 may be formed of a thermosetting adhesive agent composition. In other words, the adhesive layer 3 may include a layer formed of a thermosetting adhesive agent composition (hereinafter referred to as thermosetting adhesive layer). The adhesive layer 3 including the thermosetting adhesive layer is more suitable for joining to the protective membrane 2 by a heating/pressing treatment. The thermosetting adhesive layer is formed, for example, by applying and drying a thermosetting adhesive agent composition C.

The adhesive agent composition C may have a storage modulus G′ of 1.0×10³ Pa or more at 130 to 170° C. 130 to 170° C. corresponds to a typical curing temperature of a thermosetting resin composition and a typical temperature of a heating/pressing treatment. At 130 to 170° C., the storage modulus G′ of the adhesive agent composition C may be 3.0×10³ Pa or more, 5.0×10³ Pa or more, 7.0×10³ Pa or more, 1.0×10⁴ Pa or more, 4.6×10⁴ Pa or more, 5.0×10⁴ Pa or more, 6.0×10⁴ Pa or more, 7.0×10⁴ Pa or more, 1.0×10⁵ Pa or more, 3.0×10⁵ Pa or more, 5.0×10⁵ Pa or more, 7.0×10⁵ Pa or more, or even 9.0×10⁵ Pa or more. The upper limit of the storage modulus G′ in the same temperature range is, for example, 5.0×10⁶ Pa or less. The adhesive layer 3 including the layer formed of the adhesive agent composition C has an excellent shape retention property during heating, and thus is more suitable for joining to the protective membrane 2 by a heating/pressing treatment. In addition, the fact that the storage modulus G′ of the adhesive agent composition C at 130 to 170° C. is in the above range can contribute to suppressing the permeation of the component of the adhesive layer 3 into the interior of the protective membrane 2.

The adhesive agent composition C may have a storage modulus G′ of 1.0×10⁸ Pa or less at 130 to 170° C. after thermal curing. The adhesive layer 3 including the layer formed of the adhesive agent composition C is not excessively hard, and has an excellent joining property. The storage modulus G′ at 130 to 170° C. after thermal curing may be 5.0×10⁷ Pa or less, 3.0×10⁷ Pa or less, 1.8×10⁷ Pa or less, 1.7×10⁷ Pa or less, 1.0×10⁷ Pa or less, 5.0×10⁶ Pa or less, 2.0×10⁶ Pa or less, 1.0×10⁶ Pa or less, or even 9.6×10⁵ Pa or less. The lower limit of the storage modulus G′ in the same temperature range after thermal curing is, for example, 5.0×10⁴ Pa or more.

The adhesive agent composition C may have a storage modulus G′ of 1.0×10⁵ Pa or more at 250° C. after thermal curing. The adhesive layer 3 including the layer formed of the adhesive agent composition C has excellent durability in a high-temperature treatment such as reflow soldering even when the adhesive layer 3 has a reduced area. The storage modulus G′ at 250° C. after thermal curing may be 3.0×10⁵ Pa or more, 5.0×10⁵ Pa or more, 7.0×10⁵ Pa or more, 1.0×10⁶ Pa or more, 1.1×10⁶ Pa or more, 5.0×10⁶ Pa or more, 1.0×10⁷ Pa or more, 2.0×10⁷ Pa or more, or even 2.2×10⁷ Pa or more. The upper limit of the storage modulus G′ in the same temperature range after thermal curing is, for example, 5.0×10⁸ Pa or less, and may be 1.0×10⁸ Pa or less or even 5.0×10⁷ Pa or less.

The storage modulus G′ of the adhesive agent composition C can be evaluated by using a film or a film resulting from thermal curing (22.5 mm in length and 10 mm in width) of the adhesive agent composition C as a test piece and heating the test piece at a temperature increase rate of 10° C./min using a forced vibration viscoelastic analyzer for solids. It should be noted that the direction of measurement (direction of vibration) of the test piece is set to a longitudinal direction of the test piece, and the vibration frequency is set to 1 Hz.

Examples of the adhesive agent composition C that can satisfy the above storage modulus G′ will be described below. However, the adhesive composition C is not limited to the following examples.

The adhesive agent composition C is, for example, an acrylic composition including an acrylic polymer. The acrylic composition normally includes an acrylic polymer (hereinafter referred to as “acrylic polymer D”) as a base polymer of an adhesive agent composition. A content of the acrylic polymer D in the acrylic composition is, for example, 35 weight % or more, and may be 40 weight % or more, 50 weight % or more, 60 weight % or more, 70 weight % or more, 80 weight % or more, or even 90 weight % or more. The upper limit of the content of the acrylic polymer D is, for example, 100 weight % or less, and may be 95 weight % or less, or even 90 weight % or less.

The acrylic polymer D preferably has a weight-average molecular weight of 200,000 or more, and may have a weight-average molecular weight of 400,000 or more, 600,000 or more, 800,000 or more, or even 1,000,000 or more. The upper limit of the weight-average molecular weight of the acrylic polymer D is, for example, 5,000,000 or less. In the adhesive agent composition C, the acrylic polymer D having a weight-average molecular weight of 200,000 or more may be included at a content of 35 weight % or more.

The adhesive agent composition C is thermally curable and includes a thermosetting group. The thermosetting group is, for example, at least one selected from a group consisting of an epoxy group, a hydroxyphenyl group, a carboxy group, a hydroxy group, a carbonyl group, an aziridinyl group, and an amino group. The thermosetting group may be one selected from a group consisting of an epoxy group, a hydroxyphenyl group, and a carboxy group, or may be an epoxy group and/or a hydroxyphenyl group. It should be noted that the epoxy group includes a glycidyl group.

In the adhesive agent composition C, the acrylic polymer D may have a thermosetting group. In this case, compared to a later-described case where a thermosetting resin has a thermosetting group, a crosslinking structure resulting from thermal curing can be more uniform, and the heat resistance of the cured adhesive layer resulting from thermal curing can be improved. The thermosetting group that the acrylic polymer D can have is, for example, at least one selected from a group consisting of an epoxy group, a carboxy group, a hydroxy group, a carbonyl group, an aziridinyl group, and an amino group. The thermosetting group that the acrylic polymer D can have may be an epoxy group and/or a carboxy group, or may be an epoxy group.

The acrylic polymer D has a glass transition temperature (Tg) of, for example, −15 to 40° C., and may have a glass transition temperature (Tg) of −10 to 30° C., or even −5 to 20° C.

The adhesive agent composition C may further include a thermosetting resin. In this case, a content of the thermosetting resin in the adhesive agent composition C is preferably smaller than the content of the acrylic polymer D in the adhesive agent composition C. The greater the content of the acrylic polymer D is, the more greatly the storage modulus G′ of the adhesive agent composition C at 130 to 170° C. can improve. The thermosetting resin may have a thermosetting group, and the thermosetting resin having the thermosetting group can function as a crosslinking agent. Examples of the thermosetting group are as described above.

The content of the thermosetting resin in the adhesive agent composition C is, for example, 50 weight % or less, and may be 40 weight % or less, 35 weight % or less, 30 weight % or less, 20 weight % or less, 15 weight % or less, or even 10 weight % or less. The lower limit of the content of the thermosetting resin is, for example, 0 weight % or more, and may be 5 weight % or more. The adhesive agent composition C may not include the thermosetting resin.

Examples of the thermosetting resin include a phenolic resin, an epoxy resin, a urea resin, a melamine resin, and an unsaturated polyester resin. However, the thermosetting resin is not limited to the above examples. In the case where the thermosetting resin is a phenolic resin and/or an epoxy resin, particularly a phenolic resin, the heat resistance of the cured adhesive layer resulting from thermal curing can be improved.

Examples of the phenolic resin include novolac-type phenolic resins such as phenol novolac resin, phenol biphenyl resin, phenol aralkyl resin, cresol novolac resin, tert-butylphenol novolac resin, and nonylphenol novolac resin, and resol-type phenolic resins. However, the phenolic resin is not limited to the above examples.

A hydroxyl value of the phenolic resin is, for example, 100 to 500 g/eq, and may be 100 to 400 g/eq.

The thermosetting resin has a weight-average molecular weight of, for example, 100 to 3000, and may have a weight-average molecular weight of 150 to 2000.

The thermosetting resin can be formed by a known manufacturing method.

Examples of the composition of the acrylic polymer D will be described. However, the acrylic polymer D is not limited to those having the following compositions.

The acrylic polymer D may have a structural unit E derived from at least one monomer selected from the following monomers: alkyl acrylates having an alkyl group having 1 to 8 carbon atoms, such as methyl acrylate, ethyl acrylate, propyl acrylate, butyl acrylate, pentyl acrylate, and hexyl acrylate; alkyl methacrylates having an alkyl group having 1 to 8 carbon atoms, such as methyl methacrylate, ethyl methacrylate, propyl methacrylate, butyl methacrylate, pentyl methacrylate, and hexyl methacrylate; acrylonitrile; styrene; carboxyl group-containing monomers, such as acrylic acid, methacrylic acid, carboxyethyl acrylate, carboxypentyl acrylate, itaconic acid, maleic acid, fumaric acid, and crotonic acid; acid anhydride monomers, such as maleic anhydride and itaconic anhydride; hydroxyl group-containing monomers, such as 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate, and (4-hydroxymethyl cyclohexyl)-methyl acrylate; sulfonic acid group-containing monomers, such as styrenesulfonic acid, allylsulphonic acid, 2-(meth)acrylamido-2-methylpropanesulfonic acid, (meth)acrylamide propanesulfonic acid, sulfopropyl (meth)acrylate, and (meth)acryloyloxy naphthalenesulfonic acid; and phosphate group-containing monomers, such as 2-hydroxyethyl acryloyl phosphate. A preferable example of the structural unit E is a unit derived from at least one monomer selected from a group consisting of an alkyl acrylate having an alkyl group having 1 to 4 carbon atoms, an alkyl methacrylate having an alkyl group having 1 to 4 carbon atoms, and an acrylonitrile. A more preferable example thereof is a unit derived from at least one monomer selected from a group consisting of ethyl acrylate, butyl acrylate, and acrylonitrile. The acrylic polymer D preferably has, as structural units, all of a unit derived from ethyl acrylate, a unit derived from butyl acrylate, and a unit derived from acrylonitrile. It should be noted that the structural unit E has no thermosetting group.

A content of the structural unit E in the acrylic polymer D is, for example, 70 weight % or more, and may be 80 weight % or more, or even 90 weight % or more. The acrylic polymer D may be formed of the structural unit E.

When the acrylic polymer D has a unit (acrylonitrile unit) derived from acrylonitrile, the content of this unit in the acrylic polymer D is, for example, 5 weight % or more, and may be 10 weight % or more, 15 weight % or more, or even 20 weight % or more. The upper limit of the content of this unit is, for example, 40 weight % or less.

The acrylic polymer D may have a structural unit F having a thermosetting group. Examples of the structural unit F include units derived from an alkyl acrylate in which a thermosetting group is introduced and an alkyl methacrylate in which a thermosetting group is introduced. Specific examples of the thermosetting group, the alkyl acrylate, and the alkyl methacrylate are as described above. More specific examples of the structural unit F include glycidyl methyl acrylate, glycidyl ethyl acrylate, glycidyl 2-ethylhexyl acrylate, carboxymethyl acrylate, and aziridinyl methyl acrylate. The acrylic polymer D may not have the structural unit F; however, in that case, the adhesive agent composition C normally includes the thermosetting resin having the thermosetting group.

When the acrylic polymer D has the structural unit F, a content of the structural unit F in the acrylic polymer D is, for example, 30 to 95 weight %, and may be 40 to 90 weight %. In this case, the content of the structural unit E may be outside of the range shown above as examples, and the sum of the content of the structural unit E and the content of the structural unit F is, for example, 70 weight % or more, and may be 80 weight % or more, or even 90 weight % or more. The acrylic polymer D may be formed of the structural unit E and the structural unit F.

When the acrylic polymer D has the structural unit F having an epoxy group, an epoxy value of the acrylic polymer D is, for example, 0.15 to 0.65 eq/kg, and may be 0.20 to 0.50 eq/kg.

The acrylic polymer D can be formed by a known polymerization method such as solution polymerization, bulk polymerization, suspension polymerization, or emulsion polymerization.

The adhesive agent composition C may include a filler. Examples of the filler include an inorganic filler and an organic filler. An inorganic filler is preferred in terms of improvement of handleability of the adhesive agent composition C, adjustment of melt viscosity of the adhesive agent composition C, provision of thixotropy to the adhesive agent composition C, etc.

Examples of the inorganic filler include silica, aluminum hydroxide, calcium hydroxide, magnesium hydroxide, antimony trioxide, calcium carbonate, magnesium carbonate, calcium silicate, magnesium silicate, calcium oxide, magnesium oxide, aluminum oxide, aluminum nitride, aluminum borate, and boron nitride. The silica may be crystalline silica or amorphous silica. Examples of the organic filler include polyimides, polyamide-imides, polyetheretherketone, polyetherimide, polyesterimide, nylon, and silicone.

The average particle diameter of the filler is, for example, 0.005 to 10 μm, and may be 0.05 to 1 μm. Different fillers having different average particle diameters may be combined. The average particle diameter of the filler can be determined using a photometric particle size distribution analyzer (for example, LA-910 (apparatus name) manufactured by HORIBA, LTD.).

Examples of the shape of the filler include a sphere and an ellipsoid.

The adhesive agent composition C may include an additional component other than those described above. Examples of the additional component include additives such as a flame retardant, a silane coupling agent, an ion trapping agent, and a thermal curing accelerating catalyst.

Examples of the flame retardant include antimony trioxide, antimony pentoxide, and brominated epoxy resins. Examples of the silane coupling agent include β-(3,4-epoxycyclohexyl)ethyl trimethoxysilane, γ-glycidoxypropyl trimethoxysilane, and γ-glycidoxypropyl methyldiethoxysilane. Examples of the ion trapping agent include hydrotalcites and bismuth hydroxide. Examples of the thermal curing accelerating catalyst include salts having a triphenylphosphine skeleton, an amine skeleton, a triphenylborane skeleton, or a trihalogenborane skeleton.

Examples of the pressure-sensitive adhesive agent composition that can form the layer B31 include acrylic, silicone, urethane, and rubber adhesive compositions.

The protective membrane 2 may be gas-impermeable in a thickness direction thereof or may have gas permeability in the thickness direction. In the case where the protective membrane 2 has gas permeability in the thickness direction, placement of the protective cover member 1 allows passage of gas through an opening of an object while entrance of foreign matter through the opening of the object is prevented. By allowing passage of gas, for example, adjustment of pressure and reduction of pressure variability can be achieved through the opening of the object. An example of reducing pressure variability is shown hereinafter. Sometimes, a heat treatment such as reflow soldering is performed with a semiconductor device placed to cover one opening of a through hole provided in a circuit board. With the protective cover member 1 placed to cover the other opening of the through hole, entrance of foreign matter into the device through the through hole can be reduced in the heat treatment. When the protective membrane 2 has gas permeability in the thickness direction, a heat-induced increase in pressure in the through hole is reduced and damage to the device by the pressure increase can be prevented. Examples of the semiconductor device include MEMSs such as microphones, pressure sensors, and acceleration sensors. These devices have an opening allowing gas and/or sound to pass therethrough, and can be placed on a circuit board such that the opening faces a through hole provided in the circuit board. The protective cover member 1 may be placed on a manufactured semiconductor device such that the protective cover member 1 covers an opening of the manufactured semiconductor device. The protective cover member 1 can also be placed inside this device. In the case where the protective membrane 2 has gas permeability in the thickness direction, the protective cover member 1 placed on an object can function, for example, as a gas-permeable member allowing passage of gas through an opening of the object while preventing entrance of foreign matter through the opening and/or a sound-permeable member allowing passage of sound through an opening of the object while preventing entrance of foreign matter through the opening. It should be noted that even in the case where the protective membrane 2 is gas-impermeable in the thickness direction, it is possible to transmit sound by vibration of the protective membrane 2, and therefore the protective cover member 1 placed on an object can function as a sound-permeable member.

The protective membrane 2 having gas permeability in the thickness direction has a gas permeability of, for example, 0.1 sec/100 mL or more and 10,000 sec/100 mL or less as expressed in terms of a gas permeability (Gurley air permeability) obtained according to Method B (Gurley method) of gas permeability measurement specified in JIS L1096. The lower limit of the Gurley air permeability may be 0.15 sec/100 mL or more, 0.3 sec/100 mL or more, 0.5 sec/100 mL or more, or even 0.6 sec/100 mL or more. The upper limit of the Gurley air permeability may be 5000 sec/100 mL or less, 1000 sec/100 mL or less, 300 sec/100 mL or less, 200 sec/100 mL or less, or even less than 100 sec/100 mL. The protective membrane 2 having a Gurley air permeability more than 10,000 sec/100 mL can be determined as a membrane that is gas-impermeable in a thickness direction.

The protective membrane 2 may be waterproof. The protective cover member 1 including the protective membrane 2 being waterproof can function, for example, as a waterproof gas-permeable member and/or a waterproof sound-permeable member after placed on an object. The protective membrane 2 being waterproof has a water entry pressure of, for example, 5 kPa or more. The water entry pressure is determined according to Method A (low water pressure method) or Method B (high water pressure method) of the water resistance test specified in JIS L 1092.

Examples of the material forming the protective membrane 2 include a metal, a resin, and a composite material thereof.

Examples of the resin and metal that can form the protective membrane 2 are the same as the examples of the resin and metal that can form the substrate 32 of the adhesive layer 3. However, the resin and metal that can form the protective membrane 2 are not limited to the above examples.

The protective membrane 2 may be formed of a heat-resistant material.

Examples of the heat-resistant material are as described above in the description of the substrate 32.

The protective membrane 2 may include a PTFE membrane.

The protective membrane 2 may include a porous membrane or a microporous membrane. The protective membrane 2 having gas permeability in the thickness direction can include a porous membrane or a microporous membrane. A membrane having a gas permeability of 20 sec/100 mL or less in a thickness direction thereof as expressed in terms of a Gurley number can be determined as a porous membrane, and a membrane having a gas permeability of more than 20 sec/100 mL and 10,000 sec/100 mL or less in a thickness direction thereof as expressed in terms of a Gurley number can be determined as a microporous membrane.

The porous membrane and the microporous membrane may each have an average pore diameter of 0.01 μm or more and less than 3 μm. The lower limit of the average pore diameter may be 0.01 μm or more, 0.05 μm or more, or even 0.1 μm or more. The upper limit of the average pore diameter may be 3 μm or less, less than 3 μm, 2.5 μm or less, 2 μm or less, 1.5 μm or less, or even 1 μm or less. The protective membrane 2 including the porous membrane or the microporous membrane having an average pore diameter of less than 3 μm is particularly suitable for suppressing the permeation of the component of the adhesive layer 3 upon joining the protective membrane 2 and the adhesive layer 3, especially upon joining using a heating/pressing treatment. The protective membrane 2 including the porous membrane or the microporous membrane having an average pore diameter of 0.01 μm or more is suitable for suppressing protrusion of the component of the adhesive layer 3 to the region 23 and deformation of the adhesive layer 3 upon joining the protective membrane 2 and the adhesive layer 3, especially upon joining using a heating/pressing treatment. The average pore diameter of the protective membrane can be evaluated according to ASTM F316-86.

The porous membrane may be a stretched porous membrane. The stretched porous membrane may be a stretched porous fluorine resin membrane, and particularly a stretched porous PTFE membrane. The stretched porous PTFE membrane is commonly formed by stretching a cast membrane or a paste extrusion containing PTFE particles. The stretched porous PTFE membrane is formed of fine PTFE fibrils and can have a node in which PTFE is more highly aggregated than in the fibrils. With the stretched porous PTFE membrane, it is possible to achieve both a high capability of preventing entrance of foreign matter and a high gas permeability. A known stretched porous membrane can be used as the protective membrane 2.

The protective membrane 2 having gas permeability in the thickness direction may include a perforated membrane in which a plurality of through holes connecting both principal surfaces of the membrane are formed. The perforated membrane may be a membrane formed by providing a plurality of through holes to an original membrane, such as an imperforate membrane, having a non-porous matrix structure. The perforated membrane may have no other ventilation paths in the thickness direction than the plurality of through holes. The through hole may extend in the thickness direction of the perforated membrane or may be a straight hole linearly extending in the thickness direction. An opening of the through hole may have the shape of a circle or an ellipse when viewed perpendicular to a principal surface of the perforated membrane. The perforated membrane can be formed, for example, by laser processing of the original membrane or by ion beam irradiation of the original membrane and subsequent perforation of the resulting membrane by chemical etching.

The protective membrane 2 having gas permeability in the thickness direction may include a non-woven fabric, a woven fabric, a mesh, or a net.

The protective membrane 2 is not limited to the above examples.

The protective membrane 2 of FIGS. 1A to 1C has the shape of a rectangle when viewed in the direction perpendicular to the principal surface of the protective membrane 2. However, the shape of the protective membrane 2 is not limited to the above example, and may be, for example, a polygon such as a square or a rectangle, a circle, or an ellipse when viewed in the above perpendicular direction. The polygon may be a regular polygon. Each corner of the polygon may be rounded.

The thickness of the protective membrane 2 is, for example, 1 to 100 μm.

The protective membrane 2 has an area of, for example, 175 mm² or less, and may have an area of 150 mm² or less, 125 mm² or less, 100 mm² or less, 75 mm² or less, 50 mm² or less, 25 mm² or less, 20 mm² or less, 15 mm² or less, 10 mm² or less, 7.5 mm² or less, 5 mm² or less, or even 2.5 mm² or less. The protective cover member 1 including the protective membrane 2 having an area in the above range is, for example, suitable for being placed on a circuit board or MEMS that normally has a small-diameter opening. The lower limit of the area of the protective membrane 2 is, for example, 0.20 mm² or more. However, the area of the protective membrane 2 may be beyond the above range depending on the type of an object on which the protective cover member 1 is placed.

The protective membrane 2 has a weight per unit area of, for example, 1 to 30 g/m². The lower limit of the weight per unit area may be 0.5 g/m² or more, 0.8 g/m² or more, 1.0 g/m² or more, 1.2 g/m² or more, 1.4 g/m² or more, 1.5 g/m² or more, 1.7 g/m² or more, 2.0 g/m² or more, 2.5 g/m² or more, or even more than 3.0 g/m². The upper limit of the weight per unit area may be 25 g/m² or less, 22 g/m² or less, 20 g/m² or less, 18 g/m² or less, 15 g/m² or less, 13 g/m² or less, 10 g/m² or less, 8 g/m² or less, 6 g/m² or less, 5 g/m² or less, 4 g/m² or less, 3 g/m² or less, 2.5 g/m² or less, 2 g/m² or less, or even 1.8 g/m² or less.

The protective membrane 2 may be subjected to various treatments such as a water repellent treatment, a liquid repellent treatment, and a coloring treatment. The various treatments can be performed based on known methods.

As the protective membrane 2, a membrane having a contact angle θ_{M} of 75 degrees or more for methanol may be used. In other words, the intrinsic contact angle θ_{M} of the protective membrane 2 may be 75 degrees or more. The intrinsic contact angle θ_{M} of the protective membrane 2 may be 77 degrees or more, 80 degrees or more, 82 degrees or more, 85 degrees or more, 87 degrees or more, 89 degrees or more, or even 90 degrees or more. The protective membrane 2 having an intrinsic contact angle θ_{M} in the above range is particularly suitable for suppressing permeation of the component of the adhesive layer 3 upon joining to the protective membrane 2, especially upon joining using a heating/pressing treatment. The intrinsic contact angle θ_{M} of the protective membrane 2 can vary depending on, for example, the material and the characteristics (thickness, average pore diameter, porosity, surface free energy, surface roughness, etc.) of the protective membrane 2 and the presence or absence of various treatments on the protective membrane 2. Depending on the material of the protective membrane 2, for example, a small average pore diameter, a low porosity, and performing a water repellent treatment or a liquid repellent treatment can contribute to increasing the intrinsic contact angle θ_{M} of the protective membrane 2.

The intrinsic contact angle θ_{M} of the protective membrane 2 incorporated into the protective cover member 1 can be specified, for example, by evaluating the contact angle θ_{M} for (I) a portion of the exposed surface 22 excluding the portion coinciding with the fixed portion 21 when viewed perpendicular to the principal surface of the protective membrane 2 (e.g., the gas passage/sound passage region 23) or (II) an exposed surface of the protective membrane 2 on the side facing the adhesive layer 3.

A preferred example of the protective cover member 1 has at least one feature selected from among the following features I to III. The preferred example may have at least two features selected from among the features I to III, or may have all the features I to III. However, the protective cover member 1 is not limited to the preferred example.

I: The intrinsic contact angle θ_{M} of the protective membrane 2 is 75 degrees or more.

II: The protective membrane 2 is a porous membrane or a microporous membrane, and an average pore diameter thereof is less than 3 μm or in the preferred range described above.

III: The adhesive layer 3 includes a thermosetting adhesive layer, the thermosetting adhesive layer is a layer formed of the thermosetting adhesive agent composition C, and the storage modulus G′ of the adhesive agent composition C at 130 to 170° C. is 1.0×10³ Pa or more or in the preferred range described above.

The protective cover member 1 of FIGS. 1A to 1C has the shape of a rectangle when viewed in the direction perpendicular to the principal surface of the protective membrane 2. However, the shape of the protective cover member 1 is not limited to the above example. The shape thereof may be a polygon including a square and a rectangle, a circle, or an ellipse when viewed in the above direction. The polygon may be a regular polygon. Each corner of the polygon may be rounded.

The area of the protective cover member 1 (the area defined when the member 1 is viewed in the direction perpendicular to the principal surface of the protective membrane 2) is, for example, 175 mm² or less, and may be 150 mm² or less, 125 mm² or less, 100 mm² or less, 75 mm² or less, 50 mm² or less, 25 mm² or less, 20 mm² or less, 15 mm² or less, 10 mm² or less, 7.5 mm² or less, 5 mm² or less, or even 2.5 mm² or less.

The protective cover member 1 having an area in the above range is, for example, suitable for being placed on a circuit board or MEMS that normally has a small-diameter opening. The lower limit of the area of the protective cover member 1 is, for example, 0.20 mm² or more. However, the area of the protective cover member 1 may be larger depending on the type of an object on which the protective cover member 1 is placed.

Examples of an object on which the protective cover member 1 is placed include semiconductor devices, such as MEMSs, and circuit boards. In other words, the protective cover member 1 may be a member for a semiconductor device, circuit board, or MEMS. The MEMS may be a non-encapsulated device having a ventilation hole on a surface of its package. Examples of the non-encapsulated MEMS include various sensors detecting the atmospheric pressure, humidity, gas, air flow, and the like and electroacoustic transducer elements such as speakers and microphones. Moreover, examples of the object are not limited to manufactured semiconductor devices and manufactured circuit boards, and may be intermediate products of such devices or boards in a manufacturing step. In this case, the protective cover member 1 can protect the intermediate product in the manufacturing step. Examples of the manufacturing step include a reflow soldering step, dicing step, bonding step, and mounting step. The manufacturing step may be a step, such as the reflow soldering step, performed at high temperatures. The term “high temperatures” as used herein is, for example, 200° C. or higher, and may be 220° C. or higher, 240° C. or higher, or even 260° C. or higher. The reflow soldering step is normally performed at about 260° C. However, the object is not limited to the above examples.

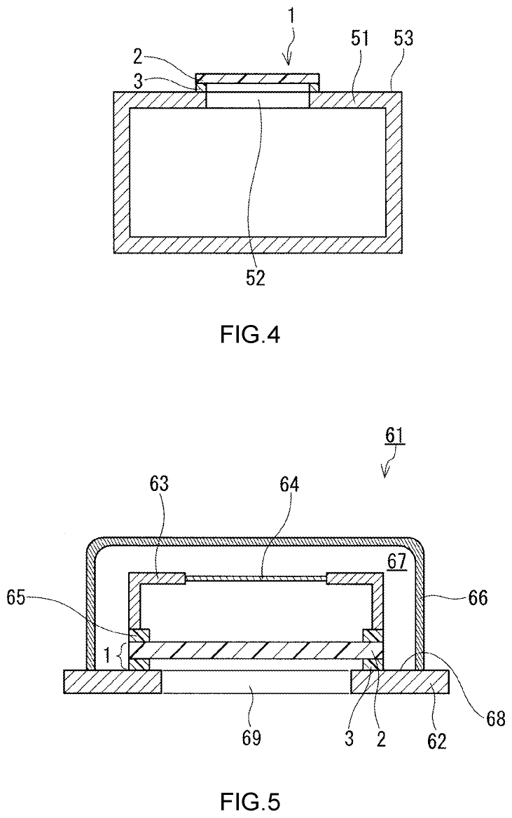

FIG. 4 shows an example of an embodiment of placing the protective cover member 1 of FIGS. 1A to 1C on an object. In the example of FIG. 4, the protective cover member 1 is placed on a face 53 of an object 51, the face 53 having an opening 52. The opening 52 is covered with the protective membrane 2 by placing the protective cover member 1. The adhesive layer 3 of FIG. 4 is positioned on the side of placement of the protective cover member 1 on the face 53 of the object 51 with respect to the protective membrane 2. The protective cover member 1 is fixed to the face 53 via the adhesive layer 3. In this example, the adhesive layer 3 forms the joining surface 11 joined to the face 53 of the object 51. A heating/pressing treatment such as hot-pressing may be used for fixing to the face 53.

A face of an object on which the protective cover member 1 can be placed is, for example, an outer surface of the object. The face may be a face inside the object. The face may be a flat face or a curved face. An opening of the object may be an opening of a recessed portion or an opening of a through hole.

The protective cover member 1 may be placed inside a semiconductor device such as a MEMS or inside a circuit board. FIG. 5 shows an example of placing the protective cover member 1 inside a MEMS. FIG. 5 shows an example of a MEMS including the protective cover member 1 of the present embodiment. A MEMS 61 of FIG. 5 is a bottom-port microphone element. The MEMS 61 includes a substrate 62 having an opening 69, a MEMS die 63 having a diaphragm 64, and a cap (cover) 66. The opening 69 functions as a sound-passing port. In an inside 67 of the MEMS 61, the protective cover member 1 is placed on an inner face 68 of the substrate 62 such that the protective membrane 2 covers the opening 69, the inner face 68 serving as a placement face. The protective cover member 1 is fixed to the inner face 68 via the adhesive layer 3. A heating/pressing treatment such as hot-pressing may be used for fixing to the inner face 68. The MEMS die 63 is joined to the protective cover member 1, more specifically, to the protective membrane 2, via an adhesive layer 65. The adhesive layer 65 is positioned opposite to the adhesive layer 3 with respect to the protective membrane 2 and is in contact with the protective membrane 2. Moreover, the adhesive layer 65 overlaps the fixed portion 21 of the protective membrane 2 (in the example in FIG. 5, coincides with the fixed portion 21) when viewed in the direction perpendicular to the principal surface of the protective membrane 2.

The adhesive layer 65 is formed, for example, by applying an adhesive agent composition, which is the fluid 5, to the exposed surface 22 of the protective membrane 2. The adhesive agent composition forming the adhesive layer 65 may be selected from the above-described adhesive agent compositions that can form the adhesive layer 3. Since the MEMS die 63 is a minute member, an adhesive agent composition particularly suitable for application to a minute area, for example, a liquid adhesive agent, may be used for the adhesive layer 65. The liquid adhesive agent is, for example, a low-viscosity adhesive agent composition in which an alcohol such as methanol is used as a solvent. The liquid adhesive agent has a viscosity (25° C.) of, for example, 0.1 to 500 Pa·s. The viscosity of the liquid adhesive agent can be evaluated, for example, by a Brookfield B-type viscometer. The liquid adhesive agent may contain an inorganic compound such as alumina as a main component. The liquid adhesive agent may be substantially free of a polymer component that is contained in a general adhesive agent. The protective cover member 1 of the present embodiment including the protective membrane 2 having the region A is suitable for being joined to the MEMS die 63 via the adhesive layer 65, the adhesive layer 65 being formed of the liquid adhesive agent. In the present specification, the main component means a component having a largest content. A content of the main component may be 50 weight % or more, 60 weight % or more, or even 70 weight % or more.

The MEMS 61 can include any components other than those described above.

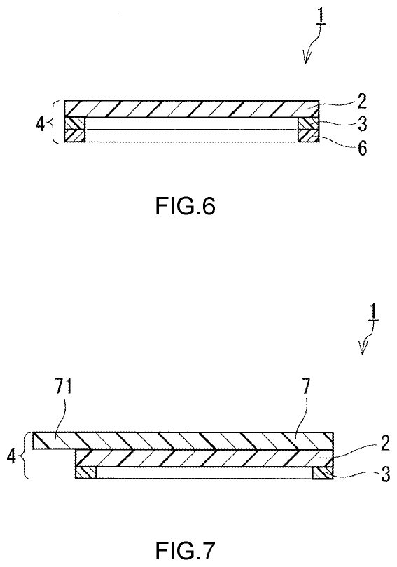

The laminate 4 of the protective cover member 1 may include a layer other than the protective membrane 2 and the adhesive layer 3. FIG. 6 shows an example of the protective cover member 1 including a further layer.

The laminate 4 of FIG. 6 further includes a substrate film 6 positioned on the adhesive layer 3 side with respect to the protective membrane 2. The substrate film 6 can increase, for example, the stiffness of the protective cover member 1. When the protective cover member 1 is supplied by a member supplying sheet, the pick-up of the protective cover member 1 from the member supplying sheet can be improved.

The substrate film 6 of FIG. 6 is placed opposite to the protective membrane 2 side with respect to the adhesive layer 3. The substrate film 6 and the adhesive layer 3 are in contact with each other. However, the position of the substrate film 6 is not limited to the above example. The substrate film 6 may be placed between the protective membrane 2 and the adhesive layer 3.

The laminate 4 of FIG. 6 includes one substrate film 6. The laminate 4 may include two or more substrate films 6, and in this case the substrate films 6 may be placed between the protective membrane 2 and the adhesive layer 3, and on the opposite side of the protective membrane 2 with respect to the adhesive layer 3.

The protective cover member 1 of FIG. 6 can be placed on the face 53 of the object 51 by a further adhesive layer provided opposite to the adhesive layer 3 side with respect to the substrate film 6. An adhesive agent composition forming the further adhesive layer can be selected from among the above-described adhesive agent compositions. The further adhesive layer may be included in the laminate 4.

The material of the substrate film 6 can be selected from among the materials shown as examples of the material of the protective membrane 2. The substrate film 6 may be formed of a heat-resistant material. Examples of the heat-resistant material are as described above in the description of the substrate 32.

FIG. 7 shows another example of the protective cover member 1 including a further layer. The laminate 4 of FIG. 7 further includes a cover film 7 positioned opposite to the adhesive layer 3 side with respect to the protective membrane 2. The cover film 7 is placed on the protective membrane 2. Another layer may be placed between the cover film 7 and the protective membrane 2. The cover film 7 can function, for example, as a protective film to protect the protective membrane 2 until the protective cover member 1 is placed on an object. The cover film 7 may be peeled off after the protective cover member 1 is placed on the object. The cover film 7 may cover the entire protective membrane 2 or a part of the protective membrane 2 when viewed in the direction perpendicular to the principal surface of the protective membrane 2. The cover film 7 can be placed, for example, on the protective membrane 2 via an adhesive layer provided on a surface of the cover film 7, the surface being on the protective membrane 2 side. The adhesive layer is preferably a weak adhesive layer.

The cover film 7 of FIG. 7 has a tab 71 which is a portion protruding outward from the perimeter of the protective membrane 2 when viewed in the direction perpendicular to the principal surface of the protective membrane 2. The tab 71 can be used for peeling off the cover film 7. However, the shape of the cover film 7 is not limited to the above example.

Examples of the material forming the cover film 7 include a metal, a resin, and a composite material thereof. Specific examples of the material that can form the cover film 7 are the same as the specific examples of the material that can form the substrate 32.

The cover film 7 has a thickness of, for example, 200 to 1000 μm.

The protective cover member 1 can be manufactured, for example, by placing an adhesive agent composition on the principal surface of the protective membrane 2 in a predetermined pattern and forming the adhesive layer 3 from the placed adhesive agent composition. The adhesive agent composition to be placed may be a thermosetting adhesive agent composition or the adhesive agent composition C. A heating/pressing treatment may be used for forming the adhesive layer 3. According to the studies by the present inventors, the heating/pressing treatment is suitable for forming the adhesive layer 3 having a reduced area. The heating/pressing treatment can be performed in a state where the adhesive agent composition is placed on the principal surface of the protective membrane 2. The temperature of the heating/pressing treatment is, for example, 50 to 300° C., and may be 50 to 250° C. The pressure is, for example, 1 to 500 kPa, and may be 1 to 100 kPa. Examples of the heating/pressing treatment include hot-pressing and heat lamination.

### [Member Supplying Sheet]

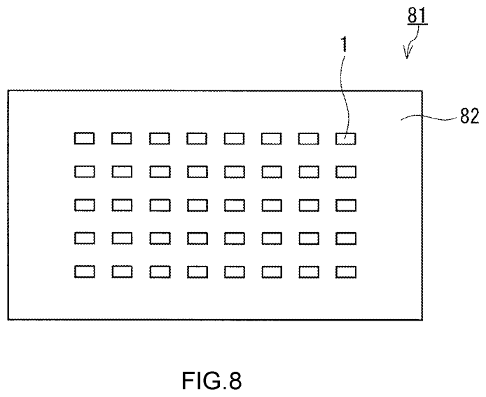

FIG. 8 shows an example of a member supplying sheet of the present invention. A member supplying sheet 81 shown in FIG. 8 includes a substrate sheet 82 and two or more protective cover members 1 placed on the substrate sheet 82. The member supplying sheet 81 is a sheet for supplying the protective cover member 1. With the use of the member supplying sheet 81, the protective cover member 1 can be effectively supplied, for example, in a step of placing the member 1 on a face of an object.

In the example shown in FIG. 8, two or more protective cover members 1 are placed on the substrate sheet 82. The number of protective cover members 1 placed on the substrate sheet 82 may be one.

In the example shown in FIG. 8, two or more protective cover members 1 are regularly placed on the substrate sheet 82. More specifically, when viewed perpendicular to the surface of the substrate sheet 82, the protective cover members 1 are placed such that a center of each protective cover member 1 is at an intersection (lattice point) of a rectangular lattice. However, the arrangement of the regularly placed protective cover members 1 is not limited to the above examples. The protective cover members 1 may be regularly placed such that the center of each protective cover member 1 is at an intersection of any of various lattices such as a square lattice, an orthorhombic lattice, or a rhombic lattice. However, the embodiment of placing the protective cover members 1 is not limited to the above example. For example, the protective cover members 1 may be placed in a staggered pattern when viewed perpendicular to the surface of the substrate sheet 82. The center of the protective cover member 1 can be determined as the center of gravity of the shape of the member 1, the shape being defined when viewed in a direction perpendicular to the surface of the substrate sheet 82.

Examples of the material forming the substrate sheet 82 include paper, a metal, a resin, and a composite material thereof. Examples of the metal include aluminum and stainless steel. Examples of the resin include polyesters such as PET, polyolefins such as polyethylene and polypropylene, and vinyl chloride (preferably soft vinyl chloride). However, the material forming the substrate sheet 82 is not limited to the above examples.

The protective cover member 1 may be placed on the substrate sheet 82 via an adhesive layer (for example, the adhesive layer 3) included in the member 1. In this case, a placement face of the substrate sheet 82 on which the protective cover member 1 is placed may be subjected to a release treatment for improving ease of release of the protective cover member 1 from the substrate sheet 82. The release treatment can be performed by a known technique.

The protective cover member 1 may be placed on the substrate sheet 82 via an adhesive layer, typically a weak adhesive layer, being provided on the placement face of the substrate sheet 82 on which the protective cover member 1 is placed.

The thickness of the substrate sheet 82 is, for example, 1 to 200 μm.

The substrate sheet 82 of FIG. 8 is in the form of a sheet having a rectangular shape. The shape of the substrate sheet 82 in the form of a sheet is not limited to the above example, and may be a polygon such as a square or a rectangle, a circle, an ellipse, or the like. When the substrate sheet 82 is in the form of a sheet, the member supplying sheet 81 can be distributed and used in the form of a sheet. The substrate sheet 82 may be in the form of a strip. In this case, the member supplying sheet 81 is also in the form of a strip. The member supplying sheet 81 in the form of a strip can be distributed in the form of a wound body wound around a winding core.

The member supplying sheet 81 can be manufactured by placing the protective cover members 1 on the surface of the substrate sheet 82.

### EXAMPLES

Hereinafter, the present invention will be described more specifically by way of examples. The present invention is not limited to examples shown below.

First, evaluation methods will be described.

### [Weight-Average Molecular Weight]

The weight-average molecular weights of acrylic polymers were evaluated by gel permeation chromatography (GPC). Four columns, which were TSK G2000H HR, G3000H HR, G4000H HR, and GMH-H HR (all manufactured by Tosoh Corporation), were connected in series and tetrahydrofuran was used as an eluent to perform GPC under the following conditions: flow rate: 1 mL/min; temperature: 40° C.; sample concentration: 0.1 weight %; amount of the tetrahydrofuran solution and the sample introduced: 500 μL. Additionally, a detector used was a differential refractometer.

### [Glass Transition Temperature (Tg)]

The Tg of each acrylic polymer was calculated using a viscoelastic analyzer (RSA-III manufactured by Rheometric Scientific Inc.) from a peak of tan δ (=loss modulus/storage modulus) evaluated under the following measurement conditions: temperature increase rate: 10° C./min; frequency: 1 MHz.

### [Epoxy Value]

The epoxy value of each acrylic polymer was evaluated according to the standards specified in JIS K 7236. The details are as follows. An amount of 4 g of an acrylic polymer to be evaluated was weighed into a conical flask having a capacity of 100 mL, to which 10 mL of chloroform was added to dissolve the acrylic polymer. Then, 30 mL of acetic acid, 5 mL of tetraethylammonium bromide, and 5 drops of a crystal violet indicator were added, and were titrated with a perchloric acid-acetic acid normal solution having a concentration of 0.1 mol/L under stirring with a magnetic stirrer. A blank test was performed in the same manner, and the epoxy value was calculated by the following equation.

$$epoxy value = [ ( V - {V}_{B} ) \times 0.1 \times F ] / 4 ( g ) \qquad Equation$$

V_{B}: the volume (mL) of the perchloric acid-acetic acid normal solution in the blank test
V: the volume (mL) of the perchloric acid-acetic acid normal solution in the titration of the specimen
F: a factor of the perchloric acid-acetic acid normal solution

### [Storage Modulus G′ at 130 to 170° C.]

The storage modulus G′ at 130 to 170° C. was evaluated for thermosetting resin compositions in the following manner. First, each produced thermosetting resin composition was applied to a surface, which had been subjected to a release treatment with silicone, of a PET sheet (thickness: 50 μm) to form a coating film (thickness: 25 μm). The coating film was dried to form a film by heating at 130° C. for a short period of time (2 minutes), which are conditions under which thermal curing of the composition hardly progresses. Next, the obtained film was peeled from the PET film and was then cut into a test piece having a length of 22.5 mm and a width of 10 mm. Subsequently, the storage modulus G′ at 130 to 170° C. was evaluated by heating the test piece from 0° C. to 260° C. at a temperature increase rate of 10° C./min using a forced vibration viscoelastic analyzer (RSA-III manufactured by Rheometric Scientific Inc.) for solids. The direction of measurement (direction of vibration) of the test piece was a longitudinal direction of the test piece, and the vibration frequency was 1 Hz.

[Storage Modulus G′ at 130 to 170° C. or at 250° C. after Thermal Curing]

The storage modulus G′ at 130 to 170° C. or at 250° C. after thermal curing was evaluated for the thermosetting resin compositions in the following manner. First, as in the evaluation of the storage modulus G′, a coating film of each thermosetting resin composition was formed on a PET film. Next, the coating film was turned into a cured film by curing at 170° C. and for 60 minutes, which are conditions under which thermal curing of the composition progresses. The obtained cured film was peeled from the PET film and was then cut into a test piece having a length of 22.5 mm and a width of 10 mm. Subsequently, the storage modulus G′ at 130 to 170° C. and the storage modulus G′ at 250° C. were evaluated by heating the test piece from 0° C. to 260° C. at a temperature increase rate of 10° C./min using the above-described viscoelastic analyzer for solids. The direction of measurement (direction of vibration) of the test piece was a longitudinal direction of the test piece, and the vibration frequency was 1 Hz.

### [Gas Permeability in Thickness Direction]

The gas permeability in the thickness direction of a protective membrane was determined as an air permeability (Gurley air permeability) according to Method B (Gurley method) of gas permeability measurement specified in JIS L1096: 2010.

### [Average Pore Diameter]

The average pore diameter of a protective membrane was determined using an Automated perm porometer, manufactured by Porous Materials Inc., which is capable of performing measurement according to ASTM F316-86.

### [Contact Angle θ_{M} for Methanol]

A contact angle θ_{M} for methanol was evaluated for a principal surface of a prepared protective membrane and an exposed surface of a protective membrane in a laminate of the protective membrane and an adhesive layer (corresponding to an exposed surface of a fixed portion of a protective membrane included in a protective cover member) using Contact Angle System OCA 30 manufactured by Data Physics Instruments GmbH, which is capable of performing evaluation according to the sessile drop method specified in JIS R3257. However, the evaluation was performed using a methanol drop having a volume of 2 μL instead of a water drop. The evaluation temperature was set to 25° C.

### [Evaluation of Spreading of Fluid 5]

The degree of spreading of the fluid 5 on the exposed surface of the protective membrane in the laminate of the protective membrane and the adhesive layer was evaluated as follows. As the fluid 5, a liquid adhesive agent was prepared by mixing an adhesive agent (TB3732, manufactured by ThreeBond, Co., Ltd.) and methanol at a weight ratio of 3:5. Next, 2 μL of the liquid adhesive agent was dropped onto the exposed surface of the protective membrane, and the height of the liquid drop immediately after the dropping was evaluated using Contact Angle System OCA 30 described above. The case where the height of the liquid drop (corresponding to the distance from the exposed surface to the top of the liquid drop) remained to be more than 0.05 mm was determined as good (∘), and the case where the height of the liquid drop was 0.05 mm or less was determined as poor (x). The evaluation was performed at 25° C.

### [Preparation of Protective Membranes]

The following PTFE membranes a to f were prepared as protective membranes.

### (PTFE Membrane a)

An amount of 100 parts by weight of PTFE fine powder (Fluon CD123E, manufactured by AGC Inc.) and 20 parts by weight of a liquid lubricant (n-dodecane, manufactured by Japan Energy Corporation) were uniformly mixed, compressed by a cylinder, and then extruded by a ram extruder to obtain a sheet-like molded body extending in a longitudinal direction. The sheet-like molded body was passed between metal rolling rolls, with the liquid lubricant contained therein, to be rolled to a thickness of 0.2 mm. Then, the liquid lubricant was removed by heating the sheet-like molded body to 150° C., and the sheet-like molded body was dried. Then, the sheet-like molded body was stretched at a ratio of 2.5 times in the longitudinal direction at 300° C. and stretched at a ratio of 20 times in a width direction at 200° C. Then, the sheet-like molded body was baked at 400° C., which is a temperature equal to or higher than the melting point of PTFE, to obtain a PTFE membrane a having a thickness of 15 μm, a surface density of 5 g/m², a gas permeability of 1.3 sec/100 mL in a thickness direction thereof, and an average pore diameter of 1 μm.

### (PTFE Membrane b)

A liquid repellent treatment was performed on the PTFE membrane a to obtain a PTFE membrane b. The liquid repellent treatment was performed by immersing the PTFE membrane a in a liquid repellent treatment liquid (solution obtained by diluting X-70-029C, manufactured by Shin-Etsu Chemical Co., Ltd., which is a liquid repellent agent, with FS thinner, manufactured by Shin-Etsu Chemical Co., Ltd., to a concentration of 1.5 weight %) for 3 seconds, pulling up the immersed PTFE membrane, and then leaving the PTFE membrane at room temperature for 30 minutes to dry the PTFE membrane. The thickness, the surface density, the gas permeability in the thickness direction, and the average pore diameter of the PTFE membrane b were 15 μm, 5.5 g/m², 4.0 sec/100 mL, and 1 μm, respectively.

### (PTFE Membrane c)

To a dispersion liquid of PTFE particles (concentration of PTFE particles: 40 mass %, average particle diameter of PTFE particles: 0.2 μm, containing 6 parts by mass of a nonionic surfactant per 100 parts by mass of PTFE), 1 part by mass of a fluorine-based surfactant (MEGAFAC F-142D, manufactured by DIC Corporation) was added per 100 parts by mass of PTFE. Next, a coating membrane (thickness: 20 μm) of the above PTFE dispersion liquid containing the fluorine-based surfactant was formed on the surface of a band-shaped polyimide substrate (thickness: 125 μm). The coating membrane was formed by immersing the polyimide substrate in the PTFE dispersion liquid and then pulling up the polyimide substrate. Next, the entirety of the substrate and the coating membrane was heated to form a cast PTFE membrane. The heating was performed in two stages, first heating (100° C., 1 minute) and subsequent second heating (390° C., 1 minute). The first heating promoted removal of the dispersion medium contained in the coating membrane, and the second heating promoted the formation of the cast membrane based on binding of the PTFE particles contained in the coating membrane. The above immersion and subsequent heating were further repeated twice, and the formed PTFE cast membrane (thickness: 25 μm) was then peeled from the polyimide substrate. Next, the peeled cast membrane was rolled in an MD direction (longitudinal direction) and further stretched in a TD direction (width direction). The rolling in the MD direction was performed by roll rolling. The rolling ratio (area ratio) was set to 2.0 times, and the temperature (roll temperature) was set to 170° C. The stretching in the TD direction was performed by a tenter stretching machine. The stretching ratio in the TD direction was set to 2.0 times, and the temperature (temperature of stretching atmosphere) was set to 300° C. Thus, a PTFE membrane c having a thickness of 10 μm, a surface density of 14 g/m², a gas permeability of 100 sec/100 mL in a thickness direction thereof, and an average pore diameter of 0.1 μm was obtained.

### (PTFE Membrane d)

NTF1033 manufactured by Nitto Denko Corporation was prepared as a PTFE membrane d. The PTFE membrane d had a thickness of 20 μm, a surface density of 4.4 g/m², a gas permeability of 0.6 sec/100 mL in a thickness direction thereof, and an average pore diameter of 3 μm.

### (PTFE Membrane e)

An amount of 100 parts by weight of PTFE fine powder (POLYFLON F101HE, manufactured by Daikin Industries, Ltd.) and 20 parts by weight of a liquid lubricant (n-dodecane, manufactured by Japan Energy Corporation) were uniformly mixed, compressed by a cylinder, and then extruded by a ram extruder to obtain a sheet-like molded body extending in a longitudinal direction. The sheet-like molded body was passed between metal rolling rolls, with the liquid lubricant contained therein, to be rolled to a thickness of 0.2 mm. Then, the liquid lubricant was removed by heating the sheet-like molded body to 150° C., and the sheet-like molded body was dried. Then, the sheet-like molded body was stretched at a ratio of 9 times in the longitudinal direction at 290° C. and stretched at a ratio of 53 times in a width direction at 150° C. Then, the sheet-like molded body was baked at 400° C., which is a temperature equal to or higher than the melting point of PTFE, to obtain a PTFE membrane e having a thickness of 3 μm, a surface density of 1.5 g/m², a gas permeability of 1.5 sec/100 mL in a thickness direction thereof, and an average pore diameter of 0.35 μm.

### (PTFE Membrane f)

A liquid repellent treatment was performed on the PTFE membrane e to obtain a PTFE membrane f. The liquid repellent treatment was performed by immersing the PTFE membrane e in a liquid repellent treatment liquid (solution obtained by diluting X-70-043, manufactured by Shin-Etsu Chemical Co., Ltd., which is a liquid repellent agent, with FS thinner, manufactured by Shin-Etsu Chemical Co., Ltd., to a concentration of 1.5 weight %) for 3 seconds, pulling up the immersed PTFE membrane, and then drying the PTFE membrane at room temperature. The thickness, the surface density, the gas permeability in the thickness direction, and the average pore diameter of the PTFE membrane f were 3 μm, 1.7 g/m², 2.0 sec/100 mL, and 0.38 μm, respectively.

The results of evaluation of the contact angle θ_{M} for the principal surface of each PTFE membrane (intrinsic contact angle θ_{M} of the PTFE membrane) are shown in Table 1 below.

TABLE 1

| PTFE membrane | a | b | c | d | e | f |
|---|---|---|---|---|---|---|
| Contact angle θ_{M} (degrees) | 73 | 90 | 85 | 89 | 74 | 80 |

### [Preparation of Adhesive Agent Compositions]

The following compositions a to c were prepared as thermosetting adhesive agent compositions to be used for an adhesive layer.

### (Composition a)

An amount of 9 parts by weight of a butyl acrylate-ethyl acrylate-acrylonitrile-acrylic acid copolymer (manufactured by Negami Chemical Industrial Co., Ltd., weight-average molecular weight: 800,000, acid value: 5 mg KOH/g, Tg: −15° C.) as the acrylic polymer D, and 26 parts by weight of a phenolic resin (MEH7851SS, manufactured by Meiwa Plastic Industries, Ltd.) and 25 parts by weight of an epoxy resin (a mixture containing YL980 manufactured by Mitsubishi Chemical Corporation and N-665-EXP-S manufactured by DIC Corporation at a weight ratio of 1:1) as a thermosetting resin were dissolved in methyl ethyl ketone, and 40 parts by weight of spherical silica (SE2050, manufactured by Admatechs Company Limited) having an average particle diameter of 500 nm was further dispersed therein to prepare a thermosetting resin composition a having a concentration of 23.6 weight %.

### (Composition b)

A thermosetting resin composition b having a concentration of 23.6 weight % was prepared in the same manner as the composition a, except that a butyl acrylate-ethyl acrylate-acrylonitrile-acrylic acid copolymer (manufactured by Negami Chemical Industrial Co., Ltd., weight-average molecular weight: 400,000, acid value: 5 mg KOH/g, Tg: −15° C.) as the acrylic polymer D, and MEH7800H manufactured by Meiwa Plastic Industries, Ltd. as a phenolic resin were used and that the materials were mixed so that the contents of the acrylic polymer D, the phenolic resin, the epoxy resin, and the silica in the resulting composition would respectively be 11 weight %, 32 weight %, 32 weight %, and 25 weight %.

### (Composition c)

A thermosetting resin composition c having a concentration of 23.6 weight % was prepared in the same manner as the composition a, except that a butyl acrylate-ethyl acrylate-acrylonitrile-glycidyl methyl acrylate copolymer (manufactured by Negami Chemical Industrial Co., Ltd., weight-average molecular weight: 800,000, epoxy value: 0.4 eq/kg, Tg: 0° C.) was used as the acrylic polymer D, and an epoxy resin was not used, and that the materials were mixed so that the contents of the acrylic polymer D, the phenolic resin, and the silica in the resulting composition would respectively be 52 weight %, 6 weight %, and 42 weight %.

The results of evaluation of the storage modulus G′ at 130 to 170° C., the storage modulus G′ at 130 to 170° C. after thermal curing, and the storage modulus G′ at 250° C. after thermal curing for the adhesive agent compositions a to c are shown in Table 2 below.

TABLE 2

| | Storage modulus G′ (Pa) | | |
|---|---|---|---|
| | Before thermal curing | After thermal curing | |
| | 130 to 170° C. | 130 to 170° C. | 250° C. |
| Composition a | 6.0 × 10⁴ | 1.8 × 10⁷ | 2.0 × 10⁷ |
| Composition b | 4.6 × 10⁴ | 1.7 × 10⁷ | 2.2 × 10⁷ |
| Composition c | 9.0 × 10⁵ | 9.6 × 10⁵ | 1.1 × 10⁶ |

### [Production of Laminates of Protective Membrane and Adhesive Layer]

Assuming a fixed portion of a protective membrane included in a protective cover member, laminates (samples 1 to 14) of a protective membrane and an adhesive layer were produced as described below. Hot-pressing was used for the production. Specifically, the production is as follows.

### (Sample 1)

First, the composition a was applied to the surface of a PET sheet (thickness: 50 μm) whose surface had been subjected to a release treatment with silicone, to form a coating membrane (thickness: 20 μm). Next, the coating membrane was dried by heating at 130° C. for 2 minutes to obtain a film. Next, the obtained film and the PTFE membrane a as a protective membrane were attached together, and the formed laminate was cut into a 20 mm×20 mm square. Next, the entire laminate was sandwiched between a pair of polyimide films (thickness: 25 μm), and was hot-pressed in the thickness direction using a hot press machine (High Precision Hot Press SA-401-M, manufactured by TESTER SANGYO CO,. LTD.). The conditions of hot-pressing were a temperature of 130° C., a pressure of 20 kPa, and a time of 13 seconds. After completion of hot-pressing, the polyimide films were peeled off to obtain a laminate of a protective membrane and an adhesive layer.

### (Samples 2 to 14)

Samples 2 to 14 which are each a laminate of a protective membrane and an adhesive layer were obtained in the same manner as Sample 1, except that a PTFE membrane, which is a protective membrane, and an adhesive agent composition were selected as shown in Table 3 below.

TABLE 3

| Sample | 1 | 2 | 3 | 4 | 5 | 6 | 7 | 8 | 9 | 10 | 11 | 12 | 13 | 14 |
|---|---|---|---|---|---|---|---|---|---|---|---|---|---|---|
| PTFE membrane | a | a | a | b | b | b | c | c | c | d | d | d | e | f |
| Adhesive agent | a | b | c | a | b | c | a | b | c | a | b | c | b | b |
| composition | | | | | | | | | | | | | | |

The evaluation results for each sample are shown in Table 4 below.

TABLE 4

| Sample | 1 | 2 | 3 | 4 | 5 | 6 | 7 | 8 | 9 | 10 | 11 | 12 | 13 | 14 |
|---|---|---|---|---|---|---|---|---|---|---|---|---|---|---|
| Contact angle | 49 | 49 | 58 | 63 | 62 | 72 | 63 | 63 | 75 | <40 | <40 | 46 | 48 | 61 |
| θ_{M} (degrees) | | | | | | | | | | | | | | |
| Evaluation of | x | x | ∘ | ∘ | ∘ | ∘ | ∘ | ∘ | ∘ | x | x | x | x | ∘ |
| spreading | | | | | | | | | | | | | | |

* “<40” indicates less than 40.

### INDUSTRIAL APPLICABILITY

The protective cover member of the present invention can be used, for example, for manufacturing a semiconductor device, such as a MEMS, and/or a circuit board including such a semiconductor device.

1. A protective cover member configured to be placed on a face of an object, the face having an opening, the protective cover member comprising a laminate, wherein
the laminate includes: a protective membrane having a shape configured to cover the opening when the protective cover member is placed on the face; and an adhesive layer, and
when a portion, of the protective membrane, coinciding with the adhesive layer when viewed in a direction perpendicular to a principal surface of the protective membrane is defined as a fixed portion of the protective membrane, an exposed surface of the protective membrane on a side opposite to a side, of the protective membrane, facing the adhesive layer has a region A overlapping the fixed portion when viewed in the perpendicular direction and having a contact angle of 55 degrees or more for methanol.

2. The protective cover member according to claim 1, wherein an entire exposed surface of the fixed portion on the opposite side has a contact angle of 55 degrees or more for methanol.

3. The protective cover member according to claim 1, wherein the fixed portion is positioned in a peripheral portion of the protective membrane when viewed in the perpendicular direction.

4. The protective cover member according to claim 1, wherein the adhesive layer is in contact with the protective membrane.

5. The protective cover member according to claim 1, wherein the adhesive layer is positioned on a side of placement of the protective cover member on the face of the object with respect to the protective membrane.

6. The protective cover member according to claim 1, wherein the adhesive layer includes a layer formed of a thermosetting adhesive agent composition.

7. The protective cover member according to claim 6, wherein the thermosetting adhesive agent composition has a storage modulus of 1.0×10³ Pa or more at 130 to 170° C.

8. The protective cover member according to claim 6, wherein the thermosetting adhesive agent composition has a storage modulus of 1.0×10⁸ Pa or less at 130 to 170° C. after thermal curing.

9. The protective cover member according to claim 1, wherein, when viewed in the direction perpendicular to the principal surface of the protective membrane,
the adhesive layer is placed on a peripheral portion of the protective membrane, and
a ratio L₂/L₁ of a length L₂ of a portion of a shortest line segment of line segments extending from a center of the protective membrane to a perimeter of the protective membrane to a length L₁ of the shortest line segment is 0.5 or less, the portion lying over the adhesive layer.

10. The protective cover member according to claim 1, wherein the protective membrane has gas permeability in a thickness direction of the protective membrane.

11. The protective cover member according to claim 1, wherein
the protective membrane includes a porous membrane or a microporous membrane, and
the porous membrane and the microporous membrane each have an average pore diameter of 0.01 μm or more and less than 3 μm.

12. The protective cover member according to claim 1, wherein the protective membrane includes a polytetrafluoroethylene membrane.

13. The protective cover member according to claim 1, wherein the protective membrane has an area of 175 mm² or less.

14. The protective cover member according to claim 1, wherein the laminate further includes a substrate film positioned on the adhesive layer side with respect to the protective membrane.

15. The protective cover member according to claim 1, being for a micro electro mechanical system (MEMS).

16. The protective cover member according to claim 15, being placed and used inside the MEMS.

17. A member supplying sheet comprising:
a substrate sheet; and
at least one protective cover member placed on the substrate sheet, wherein
the protective cover member is the protective cover member according to claim 1.

18. A micro electro mechanical system comprising the protective cover member according to claim 1.
